(19) United States
(12) Patent Application Publication
(10) Pub. No.: US 2005/0031967 A1
(43) Pub. Date: Feb. 10, 2005

(54) Photomask, method for fabricating a pattern and method for manufacturing a semiconductor device

(76) Inventor: Hitoshi Ito, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/725,570

(22) Filed: Dec. 3, 2003

(30) Foreign Application Priority Data
Aug. 7, 2003 (JP) P2003-289008

(51) Int. Cl. G03C 5/00; G03G 16/00; G03F 9/00

(52) U.S. Cl. 430/5; 430/394

(57) ABSTRACT

A photomask includes a transparent substrate; a first mask pattern disposed on a first region of the transparent substrate; a second mask pattern disposed on a second region different from the first region of the transparent substrate; and a transparent film provided on the first mask pattern, having an optical thickness configured to make a focal position of the first mask pattern deeper than a focal position of the second mask pattern.

### CROSS REFERENCE TO RELATED APPLICATIONS

This application is based upon and claims the benefit of priority from prior Japanese Patent Application P2003-289008 filed on Aug. 7, 2003; the entire contents of which are incorporated by reference herein.

### BACKGROUND OF THE INVENTION

1. Field of the Invention

The present invention relates to photolithographic technology, and particularly relates to a photomask, a method for fabricating a pattern using the photomask, and a method for manufacturing a semiconductor device.

2. Description of the Related Art

When forming a circuit pattern of a semiconductor device, a photosensitive material such as a photoresist is coated on a working film on a semiconductor substrate, which is then exposed using a reduction projection aligner and developed. When an aligner having a refraction optical system is used, a light emitted from a light source, passing through an illumination optical system and a projection optical system, and demagnifies and projects a circuit pattern of a photomask located between both optical systems onto a photoresist film. A photoresist pattern having the circuit pattern transferred thereon by development is delineated on the working film. Using the photoresist pattern as a mask, the working film is subjected to processing by use of, for example, a reactive ion etching (RIE). As a result, the circuit pattern is formed on the working film.

Generally, a resolution of the optical system of the aligner is proportional to a wavelength of the light source. Therefore, responding to the demand for finer dimensions of semiconductor devices, the wavelength of the light source has been shortened. In addition, a depth of focus of the optical system is also proportional to the wavelength of the light source. As the wavelength of the light source is shortened, the depth of focus becomes shallow. Practically, since various factors have adverse effects on focusing, the effective depth of focus is further decreased (refer to International Electronic Device Meeting IEDM Technical Digest. Inoue, et al., 1999 pp.809-812)

The working film or an underlying film laying under the working film on a semiconductor substrate for a semiconductor device are planarized according to requirements by use of technology such as chemical mechanical polishing (CMP), so that a focal position may be properly adjusted for exposure. However, it is generally difficult to reduce a systematic step generated on a surface of an interlayer dielectric film deposited on a wiring layer, at a boundary between a dense wiring region and a sparse wiring or an isolated wiring region. It is difficult for the CMP technology to adjust a focus position on both surfaces of the interlayer dielectric films on the dense and sparse wiring regions having the systematic step generated therebetween. Consequently, a problem occurs such that a defocus is generated in one of the surfaces of the interlayer dielectric films and a proper photoresist pattern can not be delineated. Coping with such a problem regarding the systematic step, a method for arranging a dummy pattern in the sparse wiring region has been proposed (refer to Japanese Patent Laid Open No.10-223634 and Japanese Patent Laid Open No.07-74175).

However, in some cases, the proper dummy pattern cannot be easily arranged in a sparse wiring region. Therefore, it is difficult to achieve a sufficient planarization on a surface of an interlayer dielectric film for focusing. In addition, because of a shorter wavelength of a light source according to a miniaturization of the semiconductor integrated circuit pattern, the depth of focus becomes shallower. Accordingly, even if the CMP technology is applied by arranging the dummy pattern in the sparse wiring region, generation of the systematic step may not be completely suppressed. Hence, it is difficult to achieve sufficient planarization on a surface of an interlayer dielectric film for a proper depth of focus. Thus, since the depth of focus of the aligner is insufficient for the systematic step, performance for delineating a pattern and a production yield of the semiconductor device are extremely decreased due to the generation of defects such as a failure of transferring a pattern with a desired dimension, deterioration of dimensional fidelity of the circuit pattern as short or open wiring fault and a collapse or scattering of a resist pattern.

### SUMMARY OF THE INVENTION

A first aspect of the present invention inheres in a photomask including a transparent substrate; a first mask pattern disposed on a first region of the transparent substrate; a second mask pattern disposed on a second region different from the first region of the transparent substrate; and a transparent film provided on the first mask pattern, having an optical thickness configured to make a focal position of the first mask pattern deeper than a focal position of the second mask pattern.

A second aspect of the present invention inheres in a method for fabricating a pattern including coating a photoresist film above a working film covering an isolated pattern and a dense pattern provided above a substrate; exposing the photoresist film through a photomask having first and second mask patterns and a transparent film provided on the first mask pattern, the transparent film having an optical thickness configured to make a focal position of the first mask pattern deeper than a focal position of the second mask pattern; and delineating first and second photoresist patterns by transferring the first and second mask patterns onto the photoresist film on regions corresponding to the isolated pattern and the dense pattern, respectively.

A third aspect of the present invention inheres in a method for manufacturing a semiconductor device including depositing a working film above a semiconductor substrate, a systematic step being generated on a surface of the working film due to a pattern density difference between an isolated pattern and a dense pattern fabricated on the semiconductor substrate; coating a photoresist film above the working film; exposing the photoresist film through a photomask having first and second mask patterns and a transparent film provided on the first mask pattern, the transparent film having an optical thickness configured to make a focal position of the first mask pattern deeper than a focal position of the second mask pattern; delineating first and second photoresist patterns by transferring the first and second mask patterns onto the photoresist film on regions corresponding to the isolated pattern and the dense pattern, respectively; and processing the working film using the first and second photoresist patterns as masks.

### BRIEF DESCRIPTION OF DRAWINGS

FIG. 1 is a schematic cross-sectional diagram of a photomask according to an embodiment of the present invention.

FIG. 2 is a block diagram of an aligner used for description of the embodiment of the present invention.

FIGS. 3 to 9 are examples of the cross-sectional views for explaining the fabrication process of a photomask according to the embodiment of the present invention.

FIG. 10 is a schematic plan view showing one example of the photomask according to the embodiment of the present invention.

FIG. 11 is a cross-sectional view of the photomask taken along the line XI-XI in FIG. 10.

FIGS. 12 to 14 are another examples of the cross-sectional views for explaining the fabrication process of a photomask according to the embodiment of the present invention.

FIGS. 15 and 16 are cross-sectional views explaining another method for fabricating the photomask according to the embodiment of the present invention.

FIGS. 17 to 21 are cross-sectional views explaining a method for fabricating a pattern according to the embodiment of the present invention.

FIG. 22 is a view showing an example of a layout of a pattern region mixing a logic pattern region and a memory pattern region therein, which is used for explaining the embodiment of the present invention.

FIGS. 23 to 28 are cross-sectional views explaining a manufacturing method of the semiconductor device according to the embodiment of the present invention.

FIG. 29 is a schematic cross-sectional diagram of the semiconductor device according to the other embodiment of the present invention.

FIG. 30 is a schematic cross-sectional view of a photomask according to the other embodiment of the present invention.

### DETAILED DESCRIPTION OF THE INVENTION

An embodiment of the present invention will be described with reference to the accompanying drawings. It is to be noted that the same or similar reference numerals are applied to the same or similar parts and elements throughout the drawings, and the description of the same or similar parts and elements will be omitted or simplified.

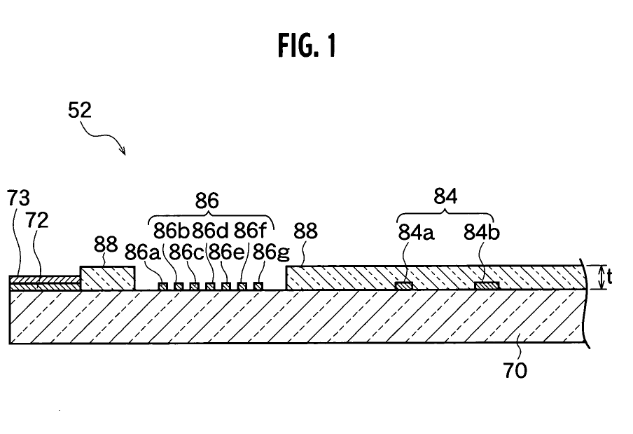

A photomask 52 according to an embodiment of the present invention, as shown in FIG. 1, includes a transparent substrate 70, a first mask pattern 84, a second mask pattern 86, and a transparent film 88. The first and second mask patterns 84, 86 are disposed on the transparent substrate 70, and the transparent film 88 having an actual film thickness of t, is located in a pattern region including the mask pattern 84 disposed therein. As the first mask pattern 84, first mask portions 84a, 84b are shown in the sectional view of FIG. 1, and as a second mask pattern 86, second mask portions 86a to 86g are shown in the cross-sectional view of FIG. 1. In addition, at an end portion of the photomask 52 shown on the left side of FIG. 1, an opaque film 73 is disposed on a mask material film 72 located on the surface of the transparent substrate 70. A quartz glass or the like subjected to mirror polishing is used for the transparent substrate 70. The first mask portions 84a, 84b, the second mask portions 86a to 86g, and the mask material film 72 are, for example, a halftone phase shift film made of molybdenum silicide (MoSi₂). An MoSi₂ film used for the halftone phase shift film has, for example, a transmittance of 6% to an exposure light and has a thickness to generate an optical phase difference of 180 degrees in relation to the exposure light. A metal film such as chromium (Cr) is used for the opaque film 73. The transparent film 88 may be a spin on glass (SOG) film including silicon oxide (SiO₂).

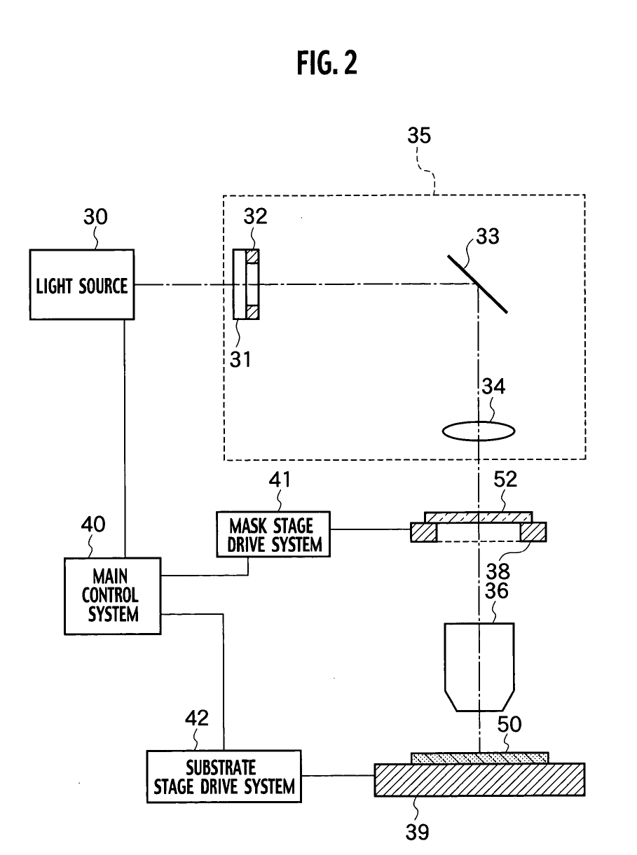

As shown in FIG. 2, an exposure system used for the embodiment of the present invention is a step and scan type excimer laser reduction projection aligner, having a reduction ratio of 1/4. Note that for the convenience of explanation, the reduction ratio of the aligner is set to 1/4. However, an arbitrary reduction ratio is also permissible. In addition, a step and repeat projection aligner (stepper) or the like may also be used for the exposure system. A light source 30 is a krypton fluoride (KrF) excimer laser having a wavelength λ of 248 nm. An exposure light irradiated from the light source 30 is incident on the photomask 52 through an illumination optical system 35 including a fly-eye lens 31, an aperture diaphragm 32, a mirror 33, a condenser lens 34 and the like. In a projection optical system 36, the first and second mask patterns 84, 86 of the photomask 52 are projected so as to produce images on the semiconductor substrate 50. The photomask 52 and the semiconductor substrate 50 are respectively placed on a mask stage 38 and a substrate stage 39. The mask stage 38 and the substrate stage 39 are positioned along an optical axis direction, so that the first and second mask patterns 84 and 86 of the photomask 52 are focused on a surface of the semiconductor substrate 50. A main control system 40 controls a light intensity emitted from the light source 30 based on preset data, and drives the mask stage 38 and the substrate stage 39 by a mask stage drive system 41 and a substrate stage drive system 42, respectively. Then, the main control system 40 performs positioning in a plane crossing the optical axis at right angles so as to execute an exposure.

A depth of focus DOF of the projection optical system 36 of the aligner is expressed by Rayleigh's formula as follows:
DOF=k₂*λ/(NA)² (1)
where, k₂ is a process-dependent factor, and NA is a numerical aperture of a projection lens of the projection optical system 36. The depth of focus DOF calculated by formula (1) is approximately 250 nm. In order to delineate patterns of the photomask 52 without any defects, it is necessary that a sum of a focal plane variation and a surface irregularity of the projected semiconductor substrate 50 is less than the depth of focus DOF. For example, the focal plane variation may be affected by factors such as curvature of an image field due to a lens aberration or flatness of the photomask 52, reproducibility of the focal position or stability of the focus control. The surface irregularity of the semiconductor substrate 50 may be affected by factors such as a systematic step of a top layer due to underlying circuit patterns and flatness of the semiconductor substrate 50. Here, a “systematic step” is defined as a thickness difference generated on a surface of a film formed on a pattern depending on a difference of a pattern density. In addition, an “effective depth of focus D” is defined as a component of the depth of focus DOF allocated to the systematic step. The effective depth of focus D is approximately 10 to 15% of the depth of focus DOF calculated by formula (1).

In the semiconductor substrate 50, for example, an isolated pattern region such as a random logic circuit, and a dense pattern region such as a dynamic random access memory (DRAM) circuit and a static random access memory (SRAM) circuit are merged thereon. A systematic step is generated on a working film such as an insulating film deposited on a surface including the isolated pattern region and the dense pattern region, in accordance with a pattern density. When the systematic step is larger than the effective depth of focus D, the working film is planarized by a CMP method. However, it is difficult to planarize the systematic step below the effective depth of focus D by CMP. Therefore, by use of ordinary photomasks which do not have a transparent film, for example, when the second mask pattern 86 is set to focus on the surface of the working film on the dense pattern region, the focal position of the first mask pattern 84 is deviated from the surface of the working film on the isolated pattern region by more than the effective depth of focus D. Thus, the mask pattern cannot be subjected to proper processing.

In the embodiment of the present invention, a transparent film 88 is provided on the first mask pattern region 84 which is to be transferred onto the isolated pattern region. Since the transparent film 88 has a refractive index larger than that of air (approximately 1), an optical thickness of the transparent film 88 is thicker than the physical thickness. Consequently, the optical path length of the exposure light that transmits the transparent film 88 is longer by the optical thickness of transparent film 88. When the optical path length of the transparent film 88 corresponds to the systematic step, the first mask pattern 84 can be focused on the surface of the working film of the isolated pattern region.

An optimal film thickness t of the transparent film 88 is expressed by,
t=S/n (2)
where S is a value of the systematic step and n is the refractive index of the transparent film 88 for the wavelength of the exposure light. In addition, the optical thickness T of the transparent film 88 is expressed by,
T=n*t (3).

Accordingly, when the optical thickness T of the transparent film 88 corresponds to the systematic step S, the focal points of the first and second mask patterns 84, 86 to be projected are positioned on the respective surface of the working film. Therefore, the mask pattern may be transferred properly. The first mask pattern 84 may also be transferred properly onto the surface of the working film on the isolated pattern region when using the transparent film 88 having the optical thickness T with which the focal position of the first mask pattern 84 to be projected may be provided within a range of the effective depth of focus D from the surface of the working film, which is lower due to the systematic step S. More specifically, it is satisfactory that the difference between the optical thickness T of the transparent film 88 and the systematic step S is within a range of the effective depth of focus D as shown by the following formula:
|T−S|≦D (4).
In the embodiment of the present invention, the refractive index n of the SOG transparent film 88 is 1.52 for the KrF excimer laser having a wavelength of 248 nm. For example, when the effective depth of focus D is approximately 30 nm and the systematic step S is approximately 70 nm, the optical thickness T of the transparent film 88 may be approximately 40 to 100 nm. Therefore, the transparent film 88 may be formed with an actual film thickness of approximately 30 to 65 nm.

According to the embodiment of the present invention, the mask pattern is transferred onto the working film on the semiconductor substrate 50 having the systematic step S generated thereon due to the difference of pattern density, by using a photomask 52 including the mask pattern region. The mask pattern region further includes the transparent film so that the focus of the mask pattern to be projected may be positioned within an effective depth of focus D of the surface of the working film. Accordingly, the mask pattern can be transferred properly onto the working film having the systematic step S generated thereon. Thus, high performance for delineating a pattern and a high production yield of the semiconductor device can be achieved.

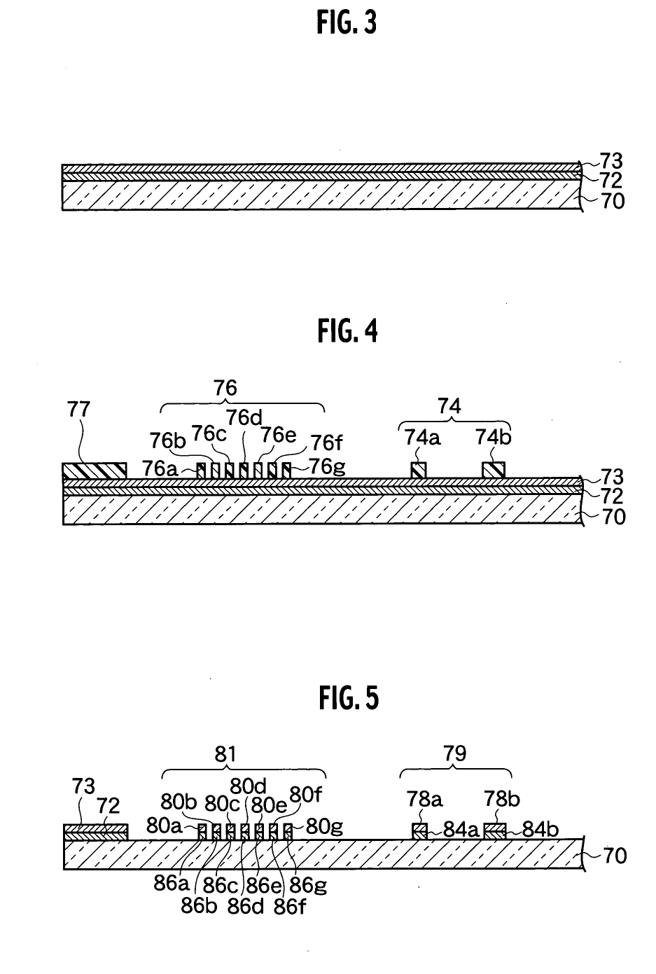

Next, a manufacturing method for the photomask 52 according to the embodiment of the present invention will be explained with reference to FIGS. 3 to 11.

(a) As shown in FIG. 3, for example, the mask material film 72 and the opaque film 73 are sequentially deposited on the transparent substrate 70 with a thickness of 100 nm, respectively, by a sputtering method.

(b) The surface of the opaque film 73 is coated with an electron beam (EB) resist. Then using an EB lithography system, as shown in FIG. 4, a first EB resist pattern 74 having first EB resist masks 74a, 74b, and a second EB resist pattern 76 having second EB resist masks 76a to 76g are delineated. An EB resist film 77 is formed on the opaque film 73 at the end portion of the transparent substrate 70 on the left side of FIG. 4.

(c) The opaque film 73 and a portion of the mask material film 72 are selectively removed by dry etching such as RIE using the first and second resist patterns 74, 76, and the EB resist film 77 as masks. Thereafter, the first and second EB resist patterns 74, 76, and the EB resist film 77 are removed, and as shown in FIG. 5, a first laminate pattern 79 including first opaque portions 78a, 78b and first mask portions 84a, 84b, and a second laminate pattern 81 including second opaque portions 80a to 80g and second mask portions 86a to 86g are formed. The opaque film 73 and the mask material film 72 are left on the end portion of the transparent substrate 70.

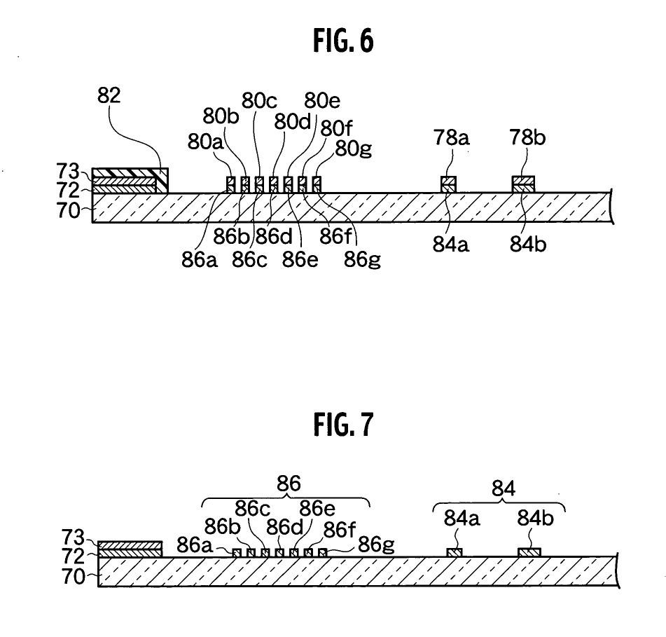

(d) The surface of the transparent substrate 70 having the first and second laminate patterns 79, 81 formed thereon is similarly coated with an EB resist. By use of the EB lithography system, as shown in FIG. 6, an EB resist film 82 is formed so as to expose the first and second opaque portions 78a, 78b, and 80a to 80g. The opaque film 73 at the end portion of the transparent substrate 70 is covered with the EB resist film 82 excluding the alignment mark region which will be described later.

(e) The first and second opaque portions 78a, 78b, and 80a to 80g are removed, for example, by a dry etching method using the EB resist film 82 as a mask. Thereafter, removing the EB resist film 82, as shown in FIG. 7, the first mask pattern 84 having the first mask portions 84a, 84b, and the second mask pattern 86 having the second mask portions 86a to 86g are formed. The formed first and second mask patterns 84, 86 are subjected to a cleaning process after a defect inspection or a defect correction. Moreover, an alignment mark is formed on a part of the opaque film 73 at the end portion of the transparent substrate 70.

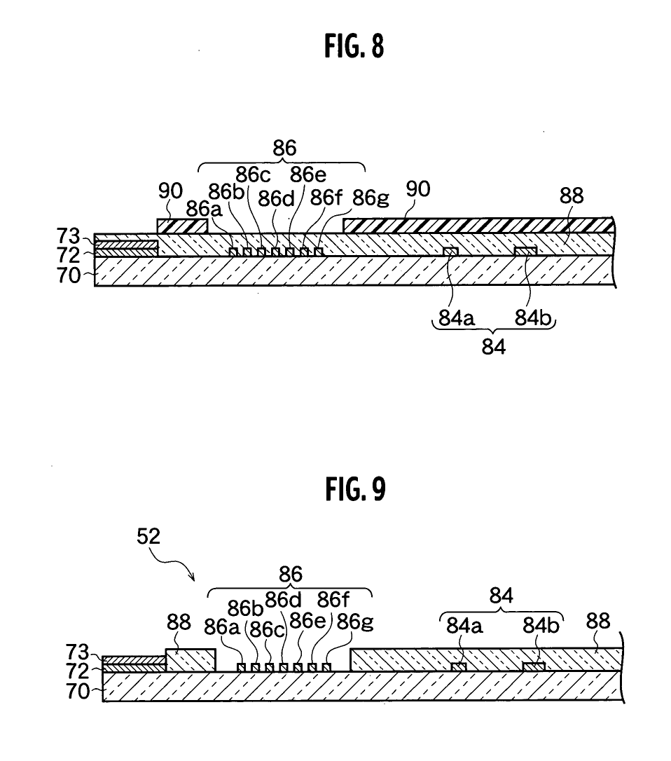

(f) As shown in FIG. 8, the surface of the transparent substrate 70 having the first and second mask patterns 84, 86 formed thereon is coated with the transparent film 88 such as an SOG film. Further, the surface of the transparent film 88 is spin-coated with an EB resist. Then, by use of an EB lithography system, an EB resist film 90 having an opening on the second mask pattern 86 and the opaque film 73 at the end portion of the transparent substrate 70 is delineated.

(g) Thereafter, as shown in FIG. 9, the transparent film 88 on the second mask pattern 86 and the opaque film 73 at the end portion of the transparent substrate 70 are selectively removed by wet etching mainly using an aqueous solution of hydrofluoric acid (HF), using the EB resist film 90 as a mask. After removing the EB resist film 90, the photomask 52 having the transparent film 88 formed on the region including the first mask pattern 84 is fabricated.

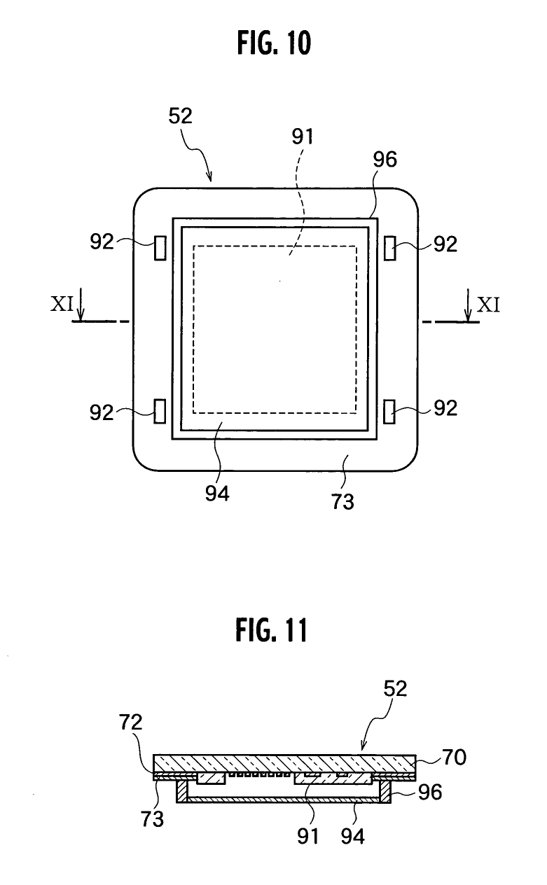

(h) The photomask 52 having the transparent film 88 formed thereon is subjected to a dust particle inspection and the like as needed. Then, as shown in FIG. 10 and FIG. 11, a pellicle 94, which is transparent to the exposure light, is provided in a pellicle frame 96 disposed on the opaque film 73 at the end portion of the transparent substrate 70, so as to cover a mask pattern region 91 including the first and second mask patterns 84, 86. In addition, a plurality of alignment marks 92 are formed on the opaque film 73 at the end portion of the transparent substrate 70.

According to the embodiment of the present invention, the mask pattern can be properly transferred onto the working film having the systematic step thereon. Therefore, it is possible to manufacture the photomask 52 so that high performance for delineating a pattern and a high production yield of the semiconductor device can be achieved.

In the embodiment of the present invention, the EB lithography system is used for the fabrication of the mask pattern. However, an optical lithography system using an ultraviolet (UV) light or a laser, an X-ray lithography system or the like may also be permissible. Moreover, an explanation has been described using quartz glass as the transparent substrate 70. However, the transparent substrate 70 is not limited to quartz glass and it is a matter of course that a transparent material such as an optical glass and a sapphire, which has enough optical transmittance to the exposure light, are also permissible. In addition, the halftone phase shift MoSi₂ film is used as the mask material film 72. However, an opaque film such as a metal, a metal alloy, a metallic oxide, an organic material and the like, having a light shielding property to the exposure light may also be permissible as the mask material film 72. Further, as the transparent film 88, a material transparent to the exposure light and having a refractive index larger than air is permissible. For example, various kinds of organic silica films, organic polymer films including various kinds of resists used for lithography, or chemical vapor deposition (CVD) films such as SiO₂ and silicon nitride (Si₃N₄) can be used as the transparent film 88.

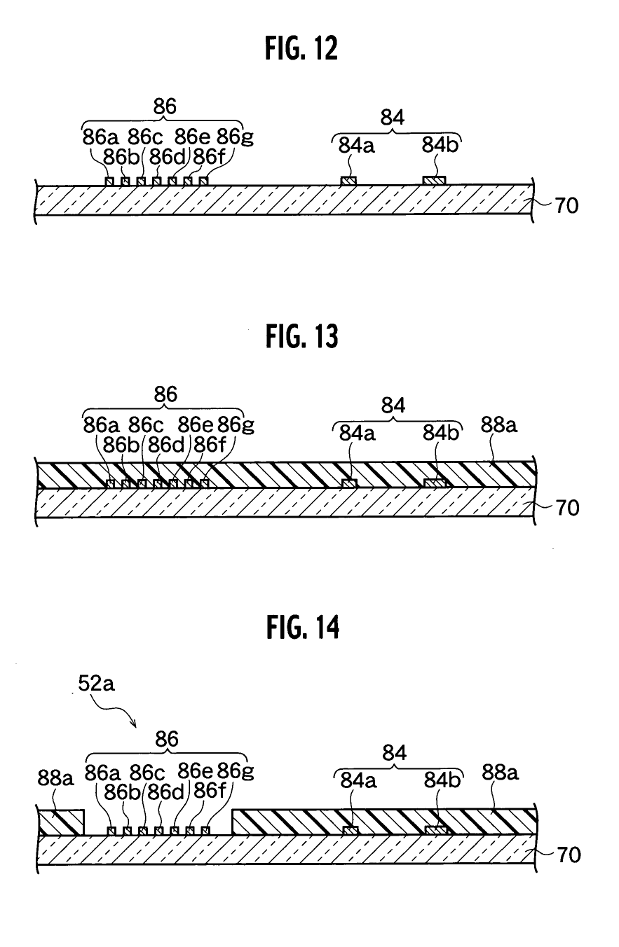

The manufacturing method of the photomask according to the embodiment is not limited to the above-described method. For example, as another manufacturing method of the photomask, after the above-described processes (a) to (f) are completed, the first and second mask patterns 84 and 86 are formed as shown in FIG. 12. As a substitute for the transparent film 88 such as the SOG film or the like of FIG. 8, as shown in FIG. 13, a transparent film 88a of an EB resist film is spin-coated. Thereafter, by use of the EB lithography system, as shown in FIG. 14, a photomask 52a having a transparent film 88a formed on the region including the first mask pattern 84 is fabricated. The EB resist film has a refractive index of 1.48 to the exposure light having a wavelength of 248 nm and has an extinction coefficient of approximately 0.005, which is small enough to be used as the transparent film 88a.

For example, when the effective depth of focus D is approximately 50 nm, and the value of the systematic step S is approximately 100 nm, the optical thickness T of the transparent film 88a is approximately 50 to 150 nm. Therefore, the transparent film 88 may be formed with a thickness t of approximately 35 to 100 nm.

In the manufacturing method of a photomask 52a, the coating process of the transparent film 88 and the etching process of the transparent film 88 by lithography are omitted. Thus, it is possible to simplify the manufacturing process to only exposing and developing of the transparent film 88a of the EB resist film and to reduce the manufacturing cost.

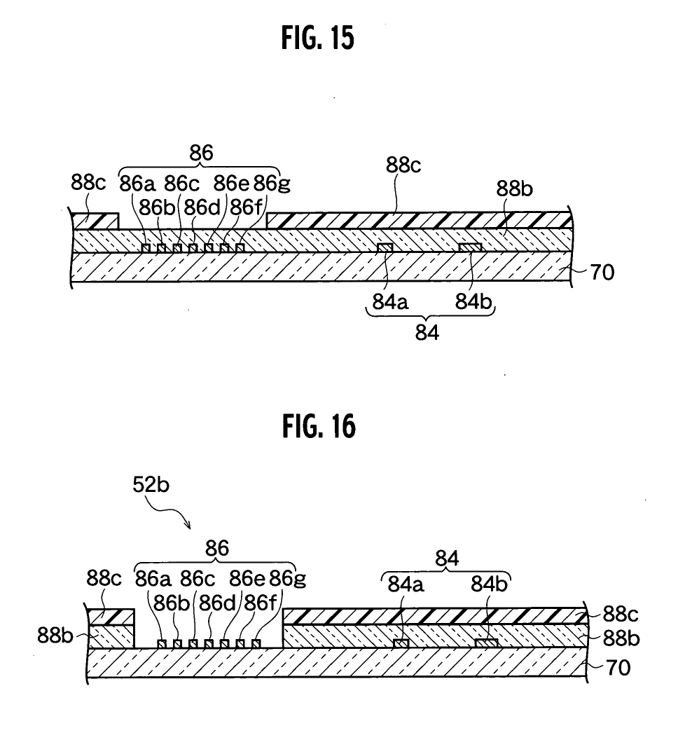

In addition, as another manufacturing method of the photomask, after the above-described processes (a) to (e) are completed, similarly to the process (f), as shown in FIG. 15, the surface of the transparent substrate 70 having the first and second mask patterns 84, 86 is coated with a first transparent SOG film 88b. Further, an EB resist film is spin-coated onto a surface of the first transparent film 88b, and by use of the EB lithography system, a second transparent film 88c of the EB resist film having an opening on the second mask pattern 86 is delineated. Thereafter, as shown in FIG. 16, the first transparent film 88b on the second mask pattern region 86 is selectively removed by wet etching using an HF aqueous solution, by using the second transparent film 88c as a mask. Thus, a photomask 52b having the first and second transparent films 88b, 88c formed thereon is fabricated on the region including the first mask pattern 84. In the photomask 52b, the optical thickness T is calculated from a sum of the first and second transparent films 88b, 88c.

By other manufacturing methods according to the embodiment of the present invention, the mask pattern may be transferred onto the working film having the systematic step thereon. Thus, it is possible to manufacture the photomask so that high performance for delineating a pattern and a high production yield of the semiconductor device can be achieved.

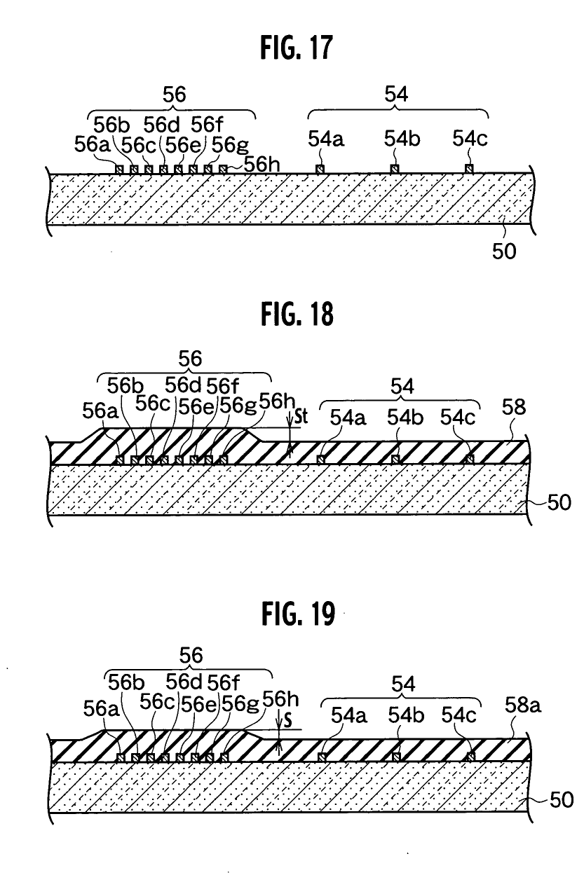

A method for fabricating a pattern according to the embodiment of the present invention will be explained with reference to FIGS. 17 to 21. For explanation, the photomask 52 and the aligner shown in FIG. 1 and FIG. 2 are used. The transparent film 88 of the photomask 52 has an actual film thickness of approximately 30 nm, and the optical thickness T is approximately 50 nm.

(a) For example, cobalt silicide (CoSi₂), nickel silicide (NiSi₂), or a refractory metal is deposited by sputtering or the like. Using lithography technology, as shown in FIG. 17, an isolated pattern 54 having first wirings 54a to 54c and a dense pattern 56 having second wirings 56a to 56h are delineated on a surface of a semiconductor substrate 50. Here, the isolated pattern 54 has a low pattern density such as a gate of a logic circuit or a gate wiring. The dense pattern 56 has a high pattern density such as a drive transistor of a DRAM circuit or a SRAM circuit, word lines or bit lines and the like.

(b) As a working film covering the isolated pattern 54 and the dense pattern 56 delineated on the semiconductor substrate 50, as shown in FIG. 18, an insulating film 58 such as borophosphosilicate glass (BPSG) is deposited by a CVD method or the like. A deposition thickness of the insulating film 58 is 600 nm on a region of the isolated pattern 54. However, on a region of the dense pattern 56, the insulating film 58 is deposited thicker than in the region of the isolated pattern 54 in accordance with the high pattern density of the dense pattern 56. Consequently, the systematic step St of 100 nm or larger is generated between the regions of the isolated pattern 54 and the dense pattern 56.

(c) In order to planarize the thick insulating film 58 deposited on the dense pattern region 56 due to the high pattern density, the insulating film 58 is polished approximately 200 nm deep from the surface of the insulating film 58 by CMP. During CMP processing, the thin insulating film 58 on the region of the isolated pattern 54 is polished more slowly than the region of the dense pattern 56. Consequently, as shown in FIG. 19, the insulating film 58a is planarized, and a resulting systematic step S between the regions of the isolated pattern 54 and the dense pattern 56 is reduced. A value of the systematic step S after planarization is 50 nm for example.

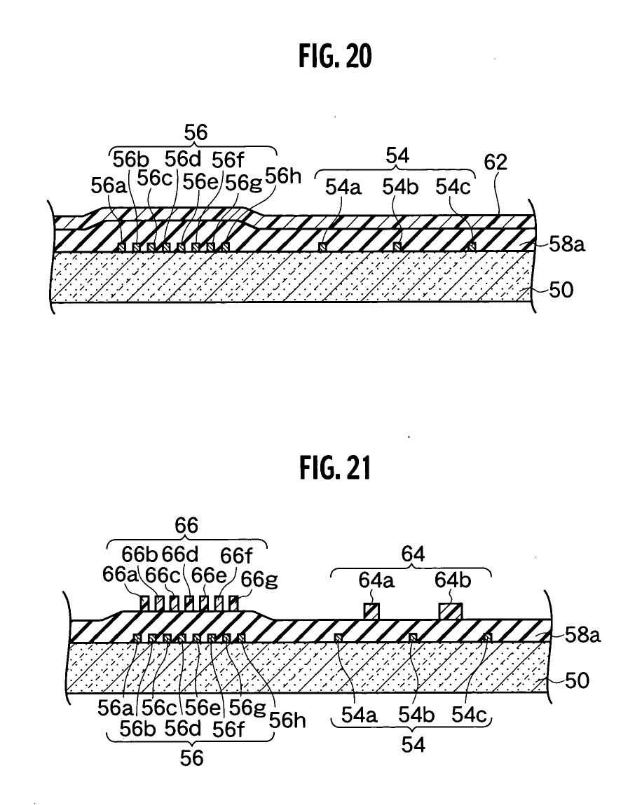

(d) As shown in FIG. 20, a photoresist film 62 used as a mask when the insulating film 58a is processed is spin-coated onto the insulating film 58a.

(e) The semiconductor substrate 50 coated with the photoresist film 62 and the photomask 52 is placed on the substrate stage 39 and the mask stage 38 of the aligner, respectively. Then, by use of the alignment mark 92 of the photomask 52 of FIG. 10, initial positioning is executed by the mask stage drive system 41 and the substrate stage drive system 42. Thereafter, focusing on the surface of the photoresist film 62 on the dense pattern region 56, the second mask pattern 86 of the photomask 52 is projected thereon. The transparent film 88 on the first mask pattern 84 has an optical thickness T of approximately 50 nm. Therefore, the first mask pattern 84 is projected by focusing on the surface of the photoresist film 62 of the isolated pattern region 54. After the exposure is completed, the photoresist film 62 is developed. Accordingly, as shown in FIG. 21, a first photoresist pattern 64 and a second photoresist pattern 66 are transferred. The first photoresist pattern 64 includes first photoresist masks 64a, 64b, and the second photoresist pattern 66 includes second photoresist masks 66a to 66g on the insulating film 58a, respectively.

For example, a defect density of the transferred resist pattern, when using the photomask without the transparent film 88, is 10/cm². On the other hand, by use of the photomask 52 according to the embodiment, any defect of the transferred resist pattern is not detected. In the embodiment of the present invention, as described above, the insulating film 58a is used as a working film. However, a wiring metal such as copper (Cu) or aluminum (Al) deposited on the insulating film 58a, or a conductive layer such as polysilicon and an insulating layer such as Si₃N₄ are also permissible as a working film.

In addition, according to the above explanation, the optical thickness T of the transparent film 88 of the photomask 52 is substantially identical to the systematic step S of the insulating film 58a after CMP processing. However, the optical thickness T of the transparent film 88 is not limited to the systematic step S. For example, in the above explanation, the depth of focus DOF of the photomask 52 is approximately 250 nm on the second mask pattern region 86 without the transparent film 88. However, on the first mask pattern region 84 having the transparent film 88 formed thereon, the depth of focus DOF is 330 nm, which is increased by approximately 30%. The effective depth of focus D is 40 nm which is also an approximate 30% increase on the first mask pattern region 84 having the transparent film 88 compared with the effective depth of focus D of approximately 30 nm on the second mask pattern region 86. Accordingly, the actual film thickness t of the transparent film 88 may be within a range of approximately 7 nm to 60 nm.

In this way, according to the embodiment of the present invention, the mask pattern can be properly transferred onto the working film having a systematic step thereon. Thus, high performance for delineating a pattern and a high production yield of the semiconductor device can be achieved.

(Manufacturing Method for a Semiconductor Device)

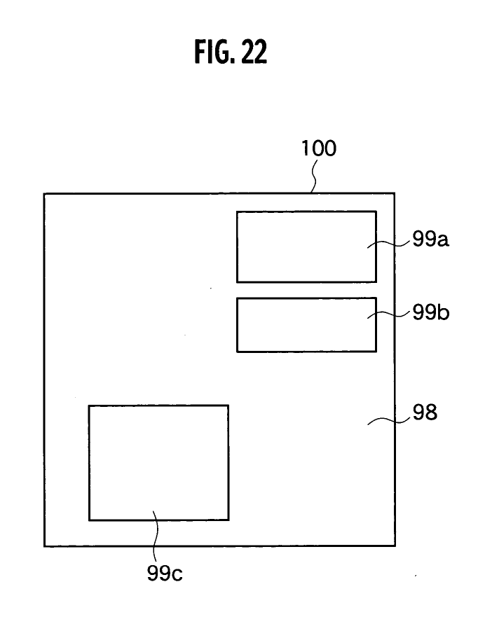

In a manufacturing method for a semiconductor device according to the embodiment of the present invention, as shown in FIG. 22, a pattern region 100 is taken as an example for explanation. The pattern region 100 is provided by merging an isolated pattern region such as a logic pattern region 98 having a logic circuit and a dense pattern region such as memory pattern regions 99a to 99c having a memory circuit. To simplify the description, one of the isolated patterns and the dense patterns are taken as an example respectively. However, a plurality of isolated patterns and dense patterns are also possible. Also, the photomask 52 and the aligner shown in FIG. 1 and FIG. 2 are used for the explanation.

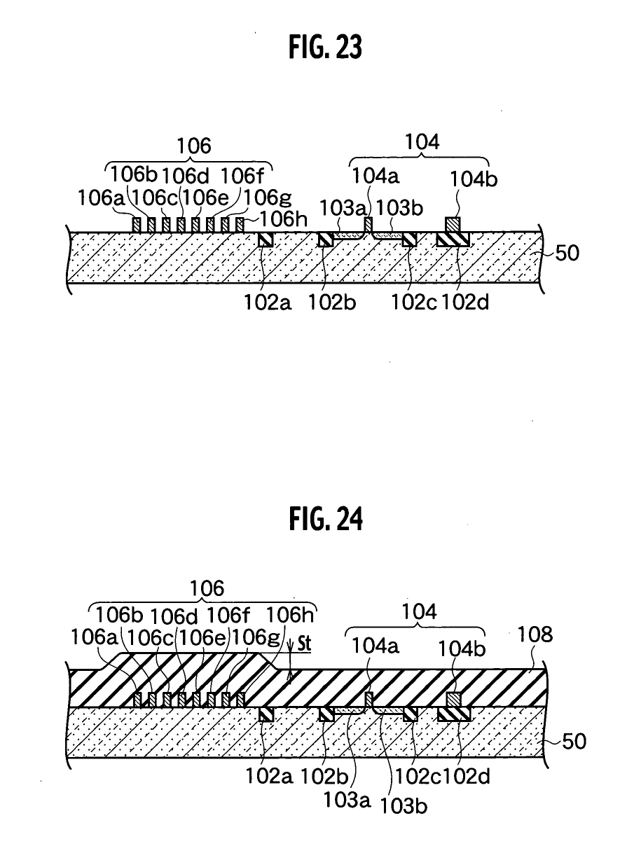

(a) As shown in FIG. 23, isolations 102a to 102d using SiO₂ for example, are formed by a shallow trench isolation technology or the like in the logic pattern region 98 shown in FIG. 22, on the surface of the semiconductor substrate 50. Thereafter, for example, a CoSi₂ film, a NiSi₂ film or a refractory metal film is deposited by sputtering. Using lithography technology or the like, an isolated pattern 104 including a gate 104a disposed between the isolations 102b and 102c through a gate insulating film (not shown in drawing), and a gate wiring 104b provided on the isolation region 102d, is formed on the semiconductor substrate 50. At the same time, a dense pattern 106 including first memory wirings 106a to 106h on the semiconductor substrate 50 is formed, for example, in the memory pattern region 99c shown in FIG. 22. Further, source/drain regions 103a, 103b are formed between the isolations 102b, 102c, and the gate 104a respectively, using ion implantation technology or the like. The source/drain regions 103a, 103b are impurity diffusion regions where impurities are doped with a high concentration.

(b) As shown in FIG. 24, an insulating film 108 such as BPSG, for example, is deposited by the CVD method or the like on the surface of the semiconductor substrate 50 having the isolated pattern 104 and the dense pattern 106 formed thereon. A deposition thickness of the insulating film 108 is 600 nm on the isolated pattern 104. However, on the dense pattern 106, the insulating film 108 is deposited thicker than on the isolated pattern 104 in accordance with the pattern density of the dense pattern 106. Consequently, a systematic step St of 100 nm or larger is generated between regions of the isolated pattern 104 and the dense pattern 106.

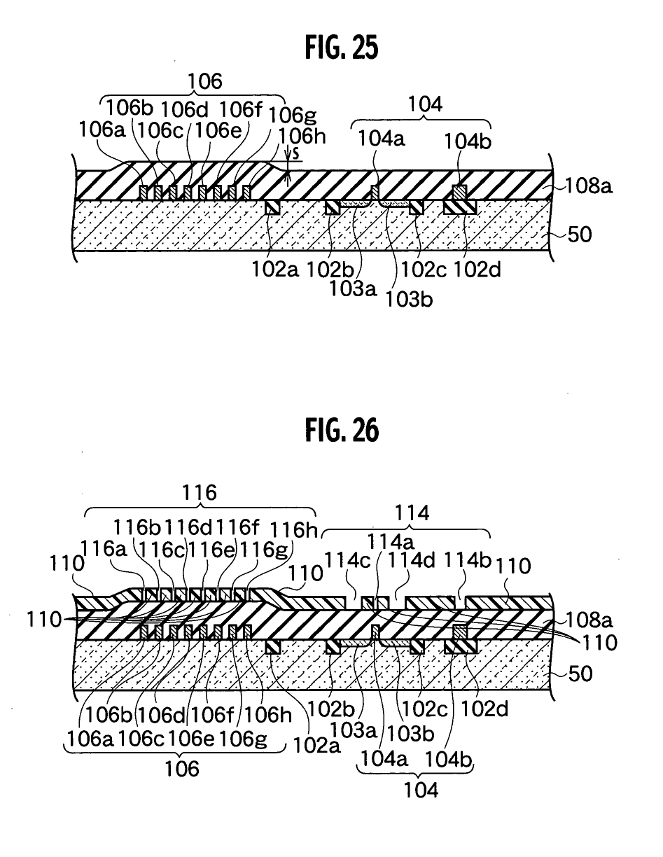

(c) In order to planarize the thick insulating film 108 deposited on the dense pattern 106 due to the high pattern density, the insulating film 108 is polished approximately 200 nm deep from the surface thereof by CMP. Consequently, as shown in FIG. 25, the insulating film 108a is planarized, and the systematic step S between the regions of the isolated pattern 104 and the dense pattern 106 is reduced. A height of the systematic step S reduced by the planarization is 50 nm, for example.

(d) A photoresist is spin-coated onto the surface of the working insulating film 108a. Thereafter, the semiconductor substrate 50 and a photomask for through holes which has a transparent film of an optical thickness T satisfying the above formula (4) provided on the mask pattern region are loaded on the aligner, so as to project on the region of the isolated pattern 104, similarly to the photomask 52 of FIG. 1. By lithography technology, as shown in FIG. 26, a photoresist film 110 including a first photoresist opening pattern 114 having first openings 114a to 114d delineated on the insulating film 108a on the isolated pattern 104, and a second photoresist opening pattern 116 having second openings 116a to 116h delineated on the insulating film 108a on the dense pattern 106, is formed. The optical thickness T of the transparent film is approximately 50 nm, which is almost identical to the systematic step S. Therefore, the first and second photoresist opening patterns 114, 116 are delineated in a desired shape. The positions of the first openings 114a to 114d correspond to the gate 104a, the gate wiring 104b, and the source/drain regions 103a and 103b, respectively. In addition, the positions of the second openings 116a to 116h correspond to the first memory wirings 106a to 106h, respectively.

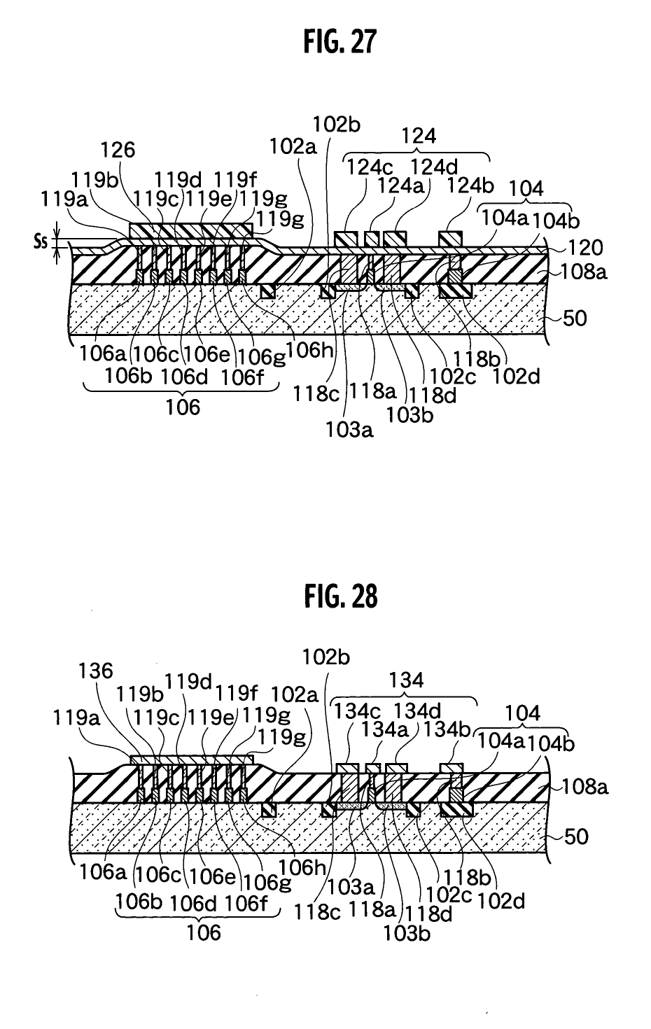

(e) The through holes are formed in the insulating film 108a below the first and second photoresist opening patterns 114 and 116, by RIE using the photoresist film 110 as a mask. As shown in FIG. 27, the through holes are filled with a metal such as Cu or Al, for example by a reflow sputtering method or the like, so as to form first plugs 118a to 118d, and second plugs 119a to 119h. The first plugs 118a to 118d are connected to the gate 104a, gate wiring 104b, and source/drain regions 103a and 103b. The second plugs 119a to 119h are connected to the first memory wirings 106a to 106h. A working film 120 such as Cu or Al is deposited by sputtering or the like on the insulating film 108a in which the first and second plugs 118a to 118d, 119a to 119h are embedded. Consequently, another systematic step Ss is formed on a surface of the working film 120 between the regions of the isolated pattern 104 and the dense pattern 106. A photoresist film is spin-coated on the surface of the working film 120. Then the semiconductor substrate 50 and a photomask for wiring are loaded on the aligner. The photomask for wiring has the mask pattern region, in which the transparent film having an optical thickness T corresponding to the systematic step Ss is provided, so as to project the mask pattern on the region of the isolated pattern 104. By lithography technology, a first photoresist pattern 124 having first photoresist masks 124a to 124d, and a second photoresist pattern 126 are delineated. The first photoresist masks 124a to 124d are respectively delineated at the positions corresponding to the positions of the first plugs 118a to 118d. The second photoresist pattern 126 has a striped pattern corresponding to bit lines of a DRAM, for example, and is delineated so as to cover the entire part of the second plugs 119a to 119h.

(f) The working film 120 is selectively removed by RIE or the like using the first and second photoresist patterns 124 and 126 as masks. As shown in FIG. 28, an upper wiring 134 having device wirings 134a to 134d connected to the first plugs 118a to 118d, and a second memory wiring 136 connected to the second plugs 119a to 119h are formed.

In this way, according to the embodiment of the present invention, the mask pattern may be properly transferred onto the working film 120 having the systematic step Ss thereon. Thus, high performance for delineating a pattern and a high production yield of the semiconductor device can be achieved.

(Other Embodiments)

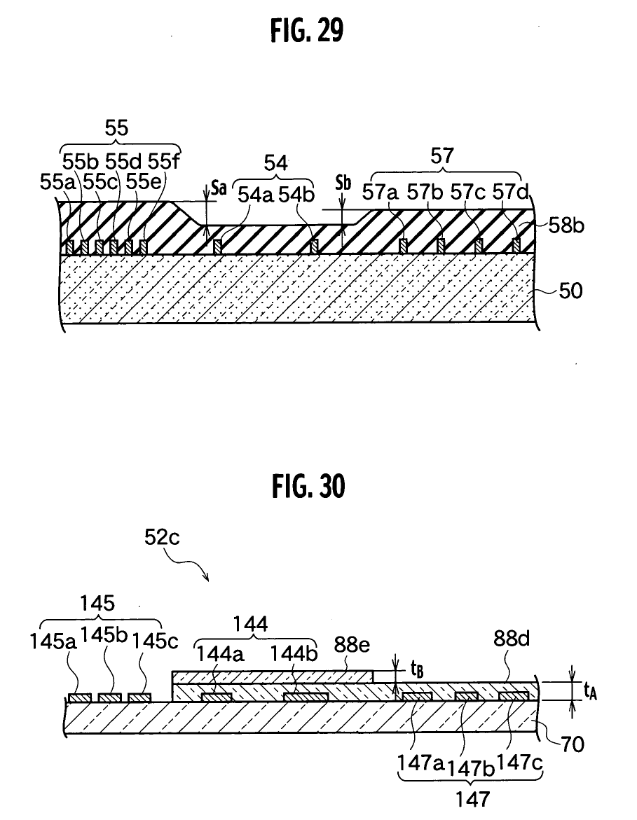

In the embodiment of the present invention, explanation has been given to the case where a single dense pattern is provided. However, a plurality of dense pattern regions with a different pattern density may also be provided. For example, as shown in FIG. 29, for an isolated pattern 54 having first wirings 54a, 54b, a first dense pattern 55 having second wirings 55a to 55f and a second dense pattern 57 having third wirings 57a to 57d are provided. Here, the first dense pattern 55 has a higher pattern density compared with the second dense pattern 57. The systematic steps Sa and Sb generated between the isolated pattern 54 and the first and second dense patterns 55, 57 are steps in accordance with the pattern density of the first and second dense patterns 55, 57. It is possible that a pattern cannot be transferred properly with the optical thickness T of the transparent film 88 or the effective depth of focus D of the photomask 52 shown in FIG. 1, for example. In such a case, a photomask 52c as shown in FIG. 30 may be used. The photomask 52c includes a first mask pattern 144, a second mask pattern 145, and a third mask pattern 147. The first mask pattern 144 has first mask portions 144a, 144b to be projected onto a region of the isolated pattern 54. The second mask pattern 145 has second mask portions 145a to 145c to be projected onto a region of the first dense pattern 55. The third mask pattern 147 has third mask portions 147a to 147c to be projected onto a region of the second dense pattern 57. In the photomask 52c, a first transparent film 88d with refractive index n_{A} and film thickness t_{A} is coated on the regions of the first and third mask patterns 144, 147. Further, a second transparent film 88e with refractive index n_{B} and film thickness t_{B} is coated on a portion of the first transparent film 88d corresponding to the first mask pattern 144. The optical thickness T_{A}=n_{A}*t_{A} of the first transparent film 88d is substantially identical to a difference between the systematic steps Sa and Sb of the dense patterns 55, 57, (Sa−Sb). In addition, the optical thickness T_{B}=n_{B}*t_{B} of the second transparent film 88e is substantially identical to the systematic step Sb generated between the isolated pattern 54 and the second dense pattern 57. That is, the optical thickness (T_{A}+T_{B}) of a composite film formed by the first and second transparent films 88d, 88e on the first mask pattern 144 is substantially identical to the systematic step Sa between the isolated pattern 54 and the first dense pattern 55. Accordingly, when the second mask pattern 145 is focused on the surface of the working film formed on the first dense pattern 55, using the photomask 52c, the first and third mask patterns 144 and 147 are projected on the surface of the working film formed on the isolated pattern 54 and the second dense pattern 57 without defocusing.

Moreover, the optical thickness (T_{A}+T_{B}) of the composite film formed by the first and second transparent films 88d and 88e may not be substantially identical to the systematic step Sa. When the systematic step Sa is within a range of the effective depth of focus D of the first mask pattern 144 to be projected, the first mask pattern 144 can be transferred onto the surface of the working film on the region of the isolated pattern 54. More specifically, it is satisfactory that the difference between the optical thickness (T_{A}+T_{B}) of the composite film and the systematic step Sa is within a range of the effective depth of focus D as shown by formula (5) corresponding to the formula (4):
|(T_{A}+T_{B})−Sa|≦D (5).

Further, even when there are three or more dense pattern regions, similarly, the transparent film having substantially the same optical thickness with the systematic step generated in accordance with the pattern density of each dense pattern may be used. In addition, when a plurality of systematic steps are in a range for satisfying the conditions of the formula (4) or the formula (5), the transparent film having the same optical thickness can be used.

Various modifications will become possible for those skilled in the art after storing the teachings of the present disclosure without departing from the scope thereof.

1. A photomask, comprising:
a transparent substrate;
a first mask pattern disposed on a first region of the transparent substrate;
a second mask pattern disposed on a second region different from the first region of the transparent substrate; and
a transparent film provided on the first mask pattern, having an optical thickness configured to make a focal position of the first mask pattern deeper than a focal position of the second mask pattern.

2. The photomask of claim 1, wherein the optical thickness determined by a product of an actual film thickness and a refractive index of the transparent film corresponds to a systematic step generated on a surface of a working film due to a pattern density difference provided in a lower layer of the working film on a region where the first and second mask patterns are transferred.

3. The photomask of claim 2, wherein an absolute value of a difference between the optical thickness and the systematic step is less than or equal to an effective depth of focus of a projection optical system.

4. The photomask of claim 2, wherein the transparent film is a composite film.

5. The photomask of claim 4, wherein an absolute value of a difference between a sum of the optical thickness of each transparent film of the composite film and the systematic step is less than or equal to an effective depth of focus of a projection optical system.

6. The photomask of claim 1, wherein the transparent film includes a resist film.

7. The photomask of claim 2, further comprising:
a third mask pattern disposed on another region of the transparent substrate; and
another transparent film having an optical thickness corresponding to another systematic step generated on the surface of the working film due to a pattern density in the lower layer of the working film on another region where the third mask pattern is transferred.

8. A method for fabricating a pattern, comprising:
coating a photoresist film above a working film covering an isolated pattern and a dense pattern provided above a substrate;
exposing the photoresist film through a photomask having first and second mask patterns and a transparent film provided on the first mask pattern, the transparent film having an optical thickness configured to make a focal position of the first mask pattern deeper than a focal position of the second mask pattern; and
delineating first and second photoresist patterns by transferring the first and second mask patterns onto the photoresist film on regions corresponding to the isolated pattern and the dense pattern, respectively.

9. The method of claim 8, wherein a surface of the working film is polished prior to coating the photoresist film.

10. The method of claim 8, wherein the optical thickness is determined by a product of an actual film thickness and a refractive index of the transparent film corresponds to a systematic step generated on a surface of the working film due to a pattern density difference between the isolated pattern and the dense pattern.

11. The method of claim 10, wherein an absolute value of a difference between the optical thickness and the systematic step is less than or equal to an effective depth of focus of a projection optical system.

12. The method of claim 10, wherein the dense pattern includes first and second dense patterns having different pattern densities, the second mask pattern of the photomask is transferred onto the photoresist film on a region corresponding to one of the first and second dense patterns having a higher pattern density, and the photomask further has a third mask pattern to be transferred onto the photoresist film on a region corresponding to the other of the first and second dense patterns having a lower pattern density, and another transparent film having an optical thickness corresponding to another systematic step further generated on the surface of the working film due to a pattern density difference between the first dense pattern and the second dense pattern, the another transparent film being provided on the third mask pattern.

13. The method of claim 12, wherein the another transparent film is provided over the first and third mask patterns.

14. A method for manufacturing a semiconductor device, comprising:
depositing a working film above a semiconductor substrate, a systematic step being generated on a surface of the working film due to a pattern density difference between an isolated pattern and a dense pattern fabricated above the semiconductor substrate;
coating a photoresist film above the working film;
exposing the photoresist film through a photomask having first and second mask patterns and a transparent film provided on the first mask pattern, the transparent film having an optical thickness configured to make a focal position of the first mask pattern deeper than a focal position of the second mask pattern;
delineating first and second photoresist patterns by transferring the first and second mask patterns onto the photoresist film on regions corresponding to the isolated pattern and the dense pattern, respectively; and
processing the working film using the first and second photoresist patterns as masks.

15. The method of claim 14, further comprising, polishing the working film prior to coating the photoresist film.

16. The method of claim 14, wherein the optical thickness is determined by a product of an actual film thickness and a refractive index of the transparent film corresponds to the systematic step generated on the surface of the working film.

17. The method of claim 16, wherein an absolute value of a difference between the optical thickness and the systematic step is less than or equal to an effective depth of focus of a projection optical system.

18. The method of claim 16, wherein the dense pattern includes first and second dense patterns having different pattern densities, the second mask pattern of the photomask is transferred onto the photoresist film on a region corresponding to one of the first and second dense patterns having a higher pattern density, and the photomask further has a third mask pattern to be transferred onto the photoresist film on a region corresponding to the other of the first and second dense patterns having a lower pattern density, and another transparent film having an optical thickness corresponding to another systematic step further generated on the surface of the working film due to a pattern density difference between the first dense pattern and the second dense pattern, the another transparent film being provided on the third mask pattern.

19. The method of claim 18, wherein the another transparent film is provided over the first and third mask patterns.

20. The method of claim 14, wherein the isolated pattern and the dense pattern are respectively formed in a logic pattern region and a memory pattern region merged on the semiconductor substrate.
